(19) United States
(12) Patent Application Publication
(10) Pub. No.: US 2019/0144995 A1
(43) Pub. Date: May 16, 2019

(54) CHEMICAL VAPOR DEPOSITION APPARATUS

(71) Applicant: SHOWA DENKO K.K., Tokyo (JP)

(72) Inventors: Naoto ISHIBASHI, Chichibu-shi (JP); Keisuke FUKADA, Chichibu-shi (JP); Yoshikazu UMETA, Chichibu-shi (JP); Tomohiro KODAMA, Chichibu-shi (JP)

(73) Assignee: SHOWA DENKO K.K., Tokyo (JP)

(21) Appl. No.: 16/175,936

(22) Filed: Oct. 31, 2018

(30) Foreign Application Priority Data
Nov. 13, 2017 (JP) 2017-218061

(51) Int. Cl. C23C 16/44; C23C 16/32; C30B 25/14

(52) U.S. Cl. CPC C23C 16/4412; C30B 29/36; C30B 25/14; C23C 16/325

(57) ABSTRACT

A chemical vapor deposition apparatus is provided which comprises a reaction furnace in which vapor deposition is performed and an exhaust pipe which discharges a gas from an interior of the reaction furnace, wherein the exhaust pipe includes at least one of a bending part, and the bending part includes at least one of a pipe-extension part, and the pipe-extension part extends from the bending part and has a storage space in the pipe-extension part.

### BACKGROUND OF THE INVENTION

### Field of the Invention

The present invention relates a chemical vapor deposition apparatus. Priority is claimed on Japanese Patent Application No. 2017-218061, filed Nov. 13, 2017, the content of which is incorporated herein by reference.

### Description of Related Art

Chemical vapor deposition (CVD) apparatuses have been widely used as a film forming means to form various kinds of films. For example, chemical vapor deposition apparatuses are used for the growth of an epitaxial layer of silicon carbide (SiC).

In film formation using the CVD method, a crystal is grown on the surface of a substrate by supplying gases in a reaction furnace. Among the gases supplied in the reaction furnace, unreacted gases are exhausted through an exhaust pipe. There is a case in which the exhaust pipe becomes blocked due to the deposition of a byproduct generated from unreacted gases which react in the exhaust pipe.

One cause of defects occurring in the CVD apparatus is the blockage of the exhaust pipe. Periodic cleaning is required to prevent the blockage of the exhaust pipe. The throughput of the CVD apparatus is significantly reduced by the cleaning as it is not possible to operate the CVD apparatus during cleaning

Patent document 1 describes a chemical vapor deposition apparatus wherein a pipe-extension part having a deposit removal means is provided at a bending part of an exhaust pipe. Patent document 1 describes that a deposit can be removed by poking and breaking the deposit by the deposit removal means.

### PRIOR ART DOCUMENTS

### Patent Documents

Patent Document 1: Japanese Unexamined Patent Application, First Publication No. 2009-94194

### SUMMARY OF THE INVENTION

### Problems to be solved by the Invention

However, in the chemical vapor deposition apparatus described in Patent Document 1, a space between the pipe-extension part and the deposit removal means may become clogged by the deposit, and in such a case, the deposit removal means does not work properly. Furthermore, there is a problem in that the occurrence of the deposit is caused again at the place where the expelled deposit is transferred.

The present invention has been made in view of the above circumstances, and an object of the present invention is to provide a chemical vapor deposition apparatus which can prevent the blockage of an exhaust pipe.

### Means for Solving the Problem

After the intensive search, the inventors of the present invention performed studies based not on the idea of removing a deposit, but on the idea of generating a deposit at a predetermined position selectively. As the result, the inventors found that when an area where a deposit is generated is restricted, the blockage of the exhaust pipe can be prevented as the generation of a deposit can be suppressed at other areas.

That is, the present invention provide the means described below to solve the aforementioned problems.

(1) The first aspect of the present invention provides a chemical vapor deposition apparatus which includes a reaction furnace in which vapor deposition is performed and an exhaust pipe which discharges a gas from an interior of the reaction furnace, wherein the exhaust pipe includes at least one of a bending part, the bending part includes at least one of a pipe-extension part, and the pipe-extension part extends from the bending part and has a storage space in the pipe-extension part.

(2) In the chemical vapor deposition apparatus according to the aspect, the pipe-extension part may be located on the line that extends in the gas flow direction of a gas which flows into the bending part.

(3) In the chemical vapor deposition apparatus according to the aspect, a plurality of the pipe-extension parts may be provided at at least one of the bending part.

(4) In the chemical vapor deposition apparatus according to the aspect, the pipe-extension parts may be located on a line that extends in the gas flow direction of a gas, which flows into the bending part, and be located on the side which is opposite to the side provided on the flow out direction to which the gas flows out from the bending part.

(5) In the chemical vapor deposition apparatus according to the aspect, the length of the pipe-extension part may be 5 to 30 cm.

(6) In the chemical vapor deposition apparatus according to the aspect, a vapor phase growth performed in the chemical vapor deposition apparatus may be an epitaxial growth of SiC.

(7) In the chemical vapor deposition apparatus according to the aspect, the epitaxial growth of SiC may be an epitaxial growth wherein a Cl-based gas is used.

(8) In the chemical vapor deposition apparatus according to the aspect, the pressure in the reaction furnace during use may be greater than or equal to 2 KPa and smaller than or equal to 50 kPa.

### Effects of the Invention

The chemical vapor deposition apparatus according to the first aspect can prevent the blockage of the exhaust pipe.

### BRIEF DESCRIPTION OF THE DRAWINGS

FIG. 1 shows a schematic diagram view which shows a preferable example of a chemical vapor deposition apparatus according to the first aspect.

### DETAILED DESCRIPTION OF THE INVENTION

Hereinafter, embodiments of the present invention will be described with reference to the drawing in detail. In the drawing used in the following description, in order to make the features easy to understand, there is a case where characteristic portions are shown in an enlarged manner for convenience, and the dimensional ratios or the like of each constituent element may be or not be the same as the actual value. In addition, materials, dimensions and the like in the following description are mere exemplary examples, and the present disclosure is not limited thereto. Various modifications may be appropriately made in a range where the effect of the present invention can be achieved.

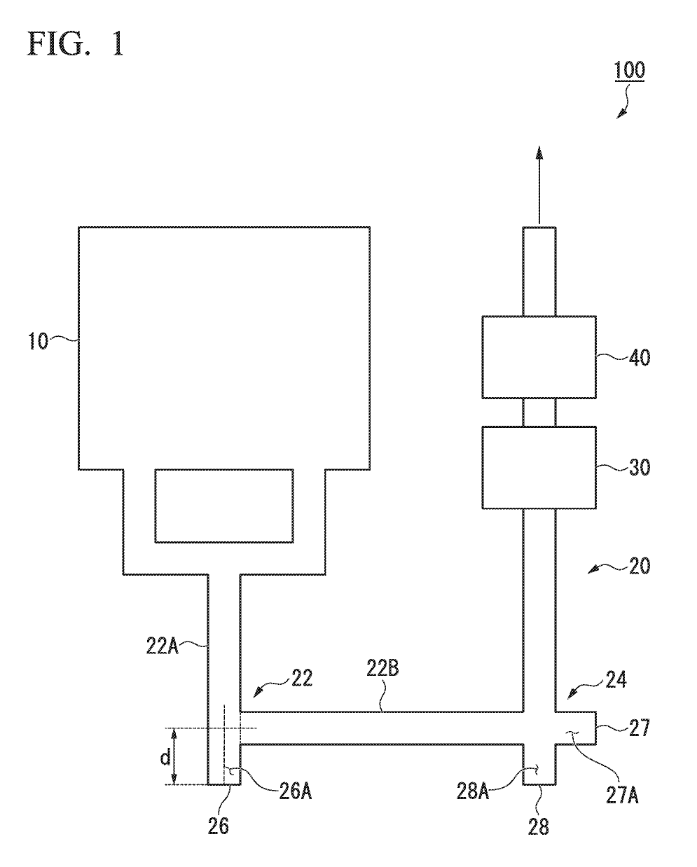

FIG. 1 shows a schematic view of a chemical vapor deposition apparatus 100 according to the present embodiment. The chemical vapor deposition apparatus 100 shown in FIG. 1 includes a reaction furnace 10, an exhaust pipe 20, a filter 30 and an exhaust pump 40.

The exhaust pipe 20 can include a plurality of bending parts. The occupied area of the chemical vapor deposition apparatus 100 can be reduced when the exhaust pipe 20 is bend by the bending parts. The bending parts are positions where the main direction of a gas flow is changed. In other words, a pipe (pipe part) is combined with another pipe via a bending part, and the extending directions of the pipes provided at the both side of the bending part are different from each other. In FIG. 1, an angle made by pipes which are respectively provided at the bending part is 90° (the combination of the pipes form L-shape). However, the structure of the exhaust pipe is not limited to this configuration. For example, the exhaust pipe may be bent at the bending part in a curved form (a U-shaped form), the exhaust pipe may be bent in a form wherein an angle made by pipes which are respectively provided at the bending part is an acute angle (a V-shaped form), or the exhaust pipe may be bent in a form wherein an angle made by pipe which are respectively provided at the bending part is an obtuse angle. The angle of the acute angle can be optionally selected in so far as the angle is less than 90°, and for example, the angle may be 1° or more, 30° or more, or 60° or more. The angle of the obtuse angle can be optionally selected in so far as the angle exceeds 90° and less than 180°, and for example, the angle may be 100° or more, 130° or more, or 150° or more. In addition, the cross section of the pipes may be a circle.

Among plurality of the bending parts which can be provided in the chemical vapor deposition apparatus 100, a first bending part 22 and a second bending part 24 have a pipe-extension part as shown in FIG. 1. It is preferable that all of the bending parts have a pipe-extension part, but it is also preferable that part of the bending parts have a pipe-extension part. Hereinafter, a pipe-extension part which is provided at the first bending part 22 is referred to a first pipe-extension part 26, and pipe-extension parts which are provided at the second bending part 24 are referred to a second pipe-extension part 27 and a third pipe-extension part 28. One pipe-extension part may be provided at one bending part, and/or a plurality of pipe-extension parts may be provided at one bending part as shown in the second bending part 24. For example, the number of a pipe-extension part provided at one bending part may be two, three or four.

The pipe-extension part extends from the bending part. The extending direction of the pipe-extension part may be different from both of the main direction of a gas flow which flows in the bending part and the main direction of a gas flow which flows out from the bending part. The first pipe-extension part 26 is located on the line that extends in the gas flow direction of a gas which flows into the first bending part 22. The second pipe-extension part 27 is located on the line that extends in the gas flow direction of a gas which flows into the second bending part 24. The third pipe-extension part 28 is located at the side opposite to the side, which is provided on the flow out direction to which the gas flows out from the second bending part 24, that is, which is opposite to the side where a flowed out gas flows. In other words, the third pipe-extension part faces a pipe which flows the flowed out gas, via the bending part.

It is preferable that the pipe-extension part is arranged on the line that extends in the flow direction of a gas which flows into the bending part. That is, it is preferable that the position of the pipe-extension part is set similar to that of the first pipe-extension part 26 provided at the first bending part 22 and that of the second pipe-extension part 27 provided at the second bending part 24 as shown in FIG. 1.

For example, a gas which flows into the first bending part 22 temporarily flows into the first pipe-extension part 26. The gas flowed into the first pipe-extension part 26 is flowing out toward the second bending part 24 from the first pipe-extension part 26, as one end of the first pipe-extension part 26 is closed. That means that turbulent flow is generated in the first pipe-extension part 26 as the first pipe-extension part 26 is provided at the aforementioned position.

Furthermore, when one bending part has a plurality of pipe-extension parts, it is preferable that the pipe-extension parts include a pipe-extension part, which is located on the line that extends in the gas flow direction of a gas which flows into the bending part, and also include a pipe-extension part, which is located on the side which is opposite to the side provided on the flow out direction where a gas flows out from the bending part, in other words, which protrudes to a side which is oppose to the flowing out side. That is, it is preferable that pipe-extension parts are provided at the positions where the second pipe-extension part 27 and the third pipe-extension part 28 are provided at the second bending part 24. When that pipe-extension parts are provided at the aforementioned positions, turbulent flow is generated in the second pipe-extension part 27 and the third pipe-extension part 28.

Turbulent flow of an exhaust gas is strongly caused in the interior of the pipe-extension part. The reason is that the pipe-extension part is arranged at a position which is different from a position located along the main stream direction of an exhaust gas. Part of the exhaust gas is retained in the pipe-extension part. When the exhaust gas is retained in the part, a reaction of raw material gases or the like included in the exhaust gas is caused, and a byproduct is deposited. That is, a deposit is generated selectively at the interior of the pipe-extension part.

The pipe-extension part has a sufficient space in the interior thereof. The byproduct is generated selectively in this space. That is, the space functions as a storage space of the deposit. As shown in FIG. 1, the first pipe-extension part 26 has a first storage space 26A, the second pipe-extension part 27 has a second storage space 27A, and the third pipe-extension part 28 had a third storage space 28A. Since the deposit selectively deposits in the storage spaces, it is possible to suppress the deposition of deposit on other areas of the exhaust pipe 20. As the result, it is possible to prevent the blockage of the exhaust pipe 20.

The length of the pipe-extension part can be selected optionally, and it is preferable that the length is greater than or equal to 5 cm and smaller than or equal to 30 cm, more preferably greater than or equal to 5 cm and smaller than or equal to 15 cm, and still more preferably greater than or equal to 5 cm and smaller than or equal to 10 cm. The length of the pipe-extension part means a distance between the end of pipe-extension part and an intersection of center lines of two pipes which are connected at the bending part. For example, with respect to the first bending part 22, the length of the pipe-extension part is a distance d from an intersection of a center line of the first pipe 22A and a center line of the second pipe 22B to the end of the first pipe-extension part 26. When the length of the pipe-extension part is included in the aforementioned range, it is possible to provide a space which ensures a sufficient storage space and to prevent an occupied area of the chemical vapor deposition apparatus from being too large. The form of the pipe-extension part can be selected optionally, and, for example, the form may be a tubular shape which has at least a bottom, or a cylindrical shape which has at least a bottom.

It is preferable that the diameter of the pipe-extension part is the same with the diameter of a pipe provided at the upstream side among two pipes which connect to the bending part. It is further preferable that the diameter of the pipe-extension part is also the same with the diameter of a pipe provided at the downstream side. For example, with respect to the first bending part 22, it is preferable that the diameter of the first pipe-extension part 26 is the same with the diameter of the first pipe 22A, and furthermore preferable that the diameter of the first pipe-extension part 26 is the same with both the diameter of the first pipe 22A and the second pipe 22B. When the diameter of the pipe-extension part is not the same with that of the pipe, turbulent flow is generated at an area where the diameter is changed. When turbulent flow is caused at an area other than the pipe-extension part, there is a possibility that deposit is generated at the area. The inner diameter of the pipe can be selected optionally, and for example, the inner diameter may be in a range of 20 mm to 80 mm. For example, as a pipe according to the NW standard, a pipe of NW25, NW40 or NW50 can be used.

A temperature of the pipe-extension part can be selected optionally, and it is preferably set such that the temperature is in the range of a room temperature to 150° C. For examples, when the temperature of the pipe-extension part is set to be included in a range which is from a room temperature to 150° C., the temperature of the pipe-extension part can be sufficiently lowered as compared to the temperature of the reaction furnace, and the pipe-extension part can efficiently accommodate a deposit.

The reaction furnace 10 is a chamber used for the chemical vapor deposition apparatus. Conventionally known furnace can be used as the reaction furnace 10.

The reaction furnace 10 is preferably a furnace which is usable for the epitaxial growth of SiC. In the case of the epitaxial growth, the growth is performed such that a temperature in the furnace increases at a high temperature of 1500° C. or more. When the epitaxial growth of SiC is performed, a raw material gas, a dopant gas, an etching gas, a carrier gas and the like can be used.

Here, a plurality of gases which can be used for crystal growth of a SiC epitaxial wafer are divided into the five types of gases which consists of “Si-based gas”, “C-based gas”, “Cl-based gas”, “dopant gas” and “other gas”.

The “Si-based gas” means a gas which includes Si as a constituent element of a molecular which constitutes the gas. For example, silane (SiCl₄), dichlorosilane (SiH₂Cl₂), trichlorosilane (SiHCl₃), tetrachoroshilane (SiCl₄) and the like can be cited. The “Si-based gas” is used as one of a raw material gas.

The “C-based gas” means a gas which includes C as a constituent element of a molecular which constitutes the gas. For example, propane (C₃H₈) and the like can be cited. The “C-based gas” can be used as one of a raw material gas.

The “Cl-based gas” means a gas which includes Cl as a constituent element of a molecular which constitutes the gas. For example, hydrogen chloride (HCl), dichlorosilane (SiH₂Cl₂), trichlorosilane (SiHCl₃), tetrachoroshilane (SiCl₄) and the like can be cited. Here, the dichlorosilane (SiH₂Cl₂), trichlorosilane (SiHCl₃) and tetrachoroshilane (SiCl₄) are also shown as the aforementioned “Si-based gas”. Similar to these compounds, there is a case that a compound is the “Cl-based gas” and also is the “Si-based gas”. The “Cl-based gas” can be used as a raw material gas or an etching gas.

The “dopant gas” is a gas which includes an element which is used as a donor or an acceptor (carrier). As the “dopant gas”, nitrogen which is used to form a N-type layer, trimethylaluminum (TMA) and triethylaluminum (TEA), which are used to form a P-type layer, and the like can be used.

The “other gas” is a gas which does not correspond the aforementioned four types of gases. For example, Ar, He, H₂ and the like are cited. These gases are used to support the generation of a SiC epitaxial wafer. For example, these gases can support a gas flow to efficiently supply a raw material gas to a SiC wafer.

These plurality of gases which have passed through the reaction furnace 10, where epitaxial growth of SiC is performed, flow into the exhaust pipe 20 in a mixed state. There is a case that a part of the gases reacts with each other and generates a byproduct. The byproduct becomes a deposit. When gases which flow in the exhaust pipe 20 includes the Cl-based gas, the viscosity of the deposit increases.

That is, when the reaction performed in the reaction furnace 10 is an epitaxial growth wherein the Cl-based gas is used, the possibility of blockage of the exhaust pipe increases. On the other hand, when the chemical vapor deposition apparatus 100 according the present embodiment is used, it is possible to prevent the deposition of the deposit in the exhaust pipe 20 even in such a case.

Furthermore, the gas pressure in the reaction furnace 10 can be selected optionally when the reaction furnace 10 is used. It is preferable that the gas pressure is preferably greater than or equal to 2 KPa and smaller than or equal to 50 kPa, and more preferably greater than or equal to 3 KPa and smaller than or equal to 30 kPa. When the gas pressure in the reaction furnace is small, the velocity of a gas flowing in the exhaust pipe 20 becomes small. When the velocity of the gas flowing in the exhaust pipe 20 decreases, a deposit tends to be easily generated and the possibility of the blockage of the exhaust pipe 20 increases. On the other hand, when the chemical vapor deposition apparatus 100 according the present embodiment is used, due to the effect of the pipe-extension part, it is possible to prevent the deposition of the deposit in the exhaust pipe 20 even in such a case. The total flow rate of the gas which flows in the reaction furnace can be selected optionally, and it is preferable that the flow rate is in a range of 50 to 200 L/min. When the gas flow rate in the reaction furnace is included in the range, the effect of preventing the blockage of a pipe is particularly remarkable.

As the filter 30 and the exhaust pump 40, conventional products can be used. Furthermore, in the chemical vapor deposition apparatus 100 according the present embodiment, the deposit is positively generated in the pipe-extension part. That is, the pipe-extension part can be considered as a pre-filter. A gas which flows into the filter 30 is the gas which has been passed through the pre-filter (pipe-extension part). Accordingly, in the chemical vapor deposition apparatus according the present embodiment, clogging of the filter 30 is prevented.

As described above, in the chemical vapor deposition apparatus according the present embodiment, it is possible to control parts where the deposit is stored in the exhaust pipe, and prevent the blockage of the exhaust pipe. As the result, operating time of the chemical vapor deposition apparatus increases and a throughput of the chemical vapor deposition apparatus increases.

Furthermore, when positions where the deposit is generated are limited in the storage spaces such as the pipe-extension part and the filter, a time required for cleaning the exhaust pipe 20 can be decreased, and a throughput of the chemical vapor deposition apparatus can increase.

Furthermore, the chemical vapor deposition apparatus 100 according the present embodiment effectively exhibits the effects when the apparatus is used for the epitaxial growth of SiC. Byproduct, which is generated by the reaction of plurality of gases usable in the epitaxial growth of SiC such as those described above and is deposited in an exhaust pipe, is a massive solid material. The property of the solid material is stable and strong, and it is difficult to remove the material by the chemical or mechanical cleaning. The chemical vapor deposition apparatus according the present embodiment can prevent the deposition of the byproduct at areas of the exhaust pipe where gases are passed through and have great effect of preventing the blockage of the pipe. The present invention provides an excellent chemical vapor deposition apparatus which can prevent the blockage of the exhaust pipe.

The preferable embodiment of the present invention is described above. However, it should be noted that the present invention is not limited to the specific embodiment, and can be carried out with appropriate modifications and changes within the scope of the present invention described in the claims

### DESCRIPTION OF THE REFERENCE SYMBOLS

10: Reaction furnace
20: Exhaust pipe
22: First bending part
22A: First pipe
22B: Second pipe
24: Second bending part
26: First pipe-extension part
26A: First storage space
27: Second pipe-extension part
27A: Second storage space
28: Third pipe-extension part
28A: Third storage space
30: Filter
40: Exhaust pump
100: Chemical vapor deposition apparatus

1. A chemical vapor deposition apparatus comprising
a reaction furnace in which vapor deposition is performed and
an exhaust pipe which discharges a gas from an interior of the reaction furnace, wherein
the exhaust pipe includes at least one of a bending part,
the bending part comprises at least one of a pipe-extension part, and
the pipe-extension part extends from the bending part and has a storage space in the pipe-extension part.

2. The chemical vapor deposition apparatus according to claim 1, wherein the pipe-extension part is located on a line that extends in a gas flow direction of a gas which flows into the bending part.

3. The chemical vapor deposition apparatus according to claim 1, wherein a plurality of the pipe-extension parts is provide at at least one of the bending part.

4. The chemical vapor deposition apparatus according to claim 3, wherein the pipe-extension parts are located on a line that extends in a gas flow direction of a gas, which flows into the bending part, and located on a side which is opposite to the side provided on a flow out direction to which the gas flows out from the bending part.

5. The chemical vapor deposition apparatus according to claim 1, wherein the length of the pipe-extension part is 5 to 30 cm.

6. The chemical vapor deposition apparatus according to claim 1, wherein a vapor phase growth performed in the chemical vapor deposition apparatus is an epitaxial growth of SiC.

7. The chemical vapor deposition apparatus according to claim 6, wherein the epitaxial growth of SiC is an epitaxial growth wherein a Cl-based gas is used.

8. The chemical vapor deposition apparatus according to claim 6, wherein the pressure in the reaction furnace during use is greater than or equal to 2 KPa and smaller than or equal to 50 kPa.
